(19) United States
(12) Patent Application Publication
(10) Pub. No.: US 2022/0170818 A1
(43) Pub. Date: Jun. 2, 2022

(54) PRIORITIZATION OF MAINTENANCE ACTIVITY BASED ON COMPUTER ANALYSIS OF MACHINE DATA WITH DIGITAL VIBRATION FREQUENCY SIMULATION

(71) Applicant: International Business Machines Corporation, Armonk, NY (US)

(72) Inventors: Mukundan Sundararajan, Bangalore (IN); Sarbajit K. Rakshit, Kolkata (IN)

(21) Appl. No.: 17/109,140

(22) Filed: Dec. 1, 2020

(51) Int. Cl. G01M 13/00; G06F 30/27; G06F 16/60

(52) U.S. Cl. CPC G01M 13/00; G06F 16/60; G06F 30/27

(57) ABSTRACT

A machine maintenance action can be detected at a location using acoustic analysis of the machine to detect a probable maintenance action. Acoustic data is received at a computer from a plurality of microphones at a location. The acoustic data is analyzed with respect to a database of specifications for the machine, and the analysis of the acoustic data includes correlating the acoustic data to the specifications of the machine stored in the database. A first measured parameter for the machine is determined as outside a first specification of the machine, and indicates a first measurement variation from the first specification of the machine. The first measurement variation is assessed to determine a reason for the first measurement variation in relation to an identified part. An alert is sent to a device with a recommendation or action regarding the identified part, based on the reason for the first measurement variation.

### BACKGROUND

The present disclosure relates to techniques for detecting machine maintenance actions at a location and more specifically, using acoustic analysis of a machine to detect a probable maintenance action.

Data from sensors and device can be placed on a plant floor to collect acoustic data from machines placed in various places on the plant floor or shop floor. Vibration, for example, from a loose-fitting on a machine mounting, or in any machine parts, can propagate through machine parts. The created vibration can propagate through the machine, body of machine, ground where it is mounted, or propagate to connectors, like pipes, etc., and if the propagated vibration matches to natural frequency or multiples on the propagation path then resonance will be created, and this might cause major damage.

Such instances are known to human experts, including, foremen, supervisors and operators who can predict with high accuracy potential conditions. Digital twin models can provide natural frequencies of the machines while in operation under different loads and while the auxiliary apparatus can be modelled, the accuracy is not achieved as the cost to do so for all conditions can be too high, and there are several non-linear relationships increasing the computing while decreasing the accuracy due to model inaccuracies. Although multiple non-linear relationships can be used to analyze acoustic data, the data cannot be encapsulated well in scientific models of the machines and a production environment.

In general, analysis of vibration activity from a machine can determine a severity of a condition related to vibration. A preventative maintenance action on the machine can be derived from the analysis of the vibration activity. However, collection of vibration data and derivation of maintenance related to vibration analysis can be improved to provide better data and improved analysis.

### SUMMARY

The present disclosure recognizes the shortcomings and problems associated with acoustic analysis of machine vibration for provide a machine maintenance action.

The present disclosure includes a method and system by which Internet of Things (IoT) devices feed, including acoustic feed, into a system for analysis. A doppler test can be performed on the propagated vibration or acoustic wave generated from different machines, ground, structure, etc. Such acoustic vibration can be caused by a loose-fit in moving parts. The analysis can identify the source of vibration, criticality of the vibration, and accordingly predict the priority of rectification so that damages can be prevented. A cognitive component in the system to which these measured inputs are fed, can determine if there is a potential for a breakdown as the combinations of possible scenarios incorporates both the theoretical values as well as practical experiential values in the training corpus.

Embodiments of the present invention can track the vibration propagation patterns, and by predicting the degree of damages because of vibration propagation, prioritize the area where preventive or reactive maintenance is to be performed. A cognitive solution according to the present invention can be run when the feeds or outputs from acoustic sensors and/or analysis of acoustic inputs into the system point to a variation in vibration, thereby providing more authentic information whether a potential breakdown situation will arise.

In one example according to embodiments of the present invention, using IoT, acoustic feed analysis along with a historical knowledge corpus, a system can identify sources of vibration in a machine part or in the associated ecosystem (like pipe line assembly, structural mounting etc.), ground structure etc., and accordingly be prioritizing the sources of vibration in the surrounding based on predicted changes of reaching at resonance frequency in the said machine, machine parts, ground, pipeline etc. (in the entire connected ecosystem). A digital twin simulation engine can show an area surrounding a machine, or an area surrounding a machine or shop floor which might be reached at the resonance frequency.

In one aspect according to the present invention, a method for detecting a machine maintenance action at a location using acoustic analysis of the machine to detect a probable maintenance action, includes receiving, at a computer, acoustic data from a plurality of microphones at a location, and the microphones receiving sounds from a machine at the location. The method includes analyzing the acoustic data with respect to a database of specifications for the machine, and the analysis of the acoustic data includes correlating the acoustic data to the specifications of the machine stored in the database. The method further includes determining when a first measured parameter for the machine, as measured as part of the analysis of the acoustic data, is outside a first specification of the machine as part of the machine specifications as indicated in the database of specifications for the machine, and indicating a first measurement variation from the first specification of the machine. The method further includes assessing when the first measurement variation outside the first specification indicates a problem, and the assessing including identifying a part associated with the machine and causally related to the first measurement variation. The method includes assessing the first measurement variation to determine a reason for the first measurement variation in relation to the identified part, and sending an alert to a device with a recommendation or action regarding the identified part, based on the reason for the first measurement variation.

In a related aspect, the device can be another machine or the device is a first device of a human resource.

In a related aspect, the recommendation or the action can be a maintenance action for the machine.

In a related aspect, the part is a part of the machine, or the part is associated to the machine which includes a machine environment part operatively communicating with the machine.

In a related aspect, the analysis of the acoustic data is generated at least in part by a cognitive system.

In a related aspect, the determining when the first measured specification for the machine being measured as part of the analysis of the acoustic data is a result, at least in part, of a digital twin simulation engine generating a digital twin of the machine.

In a related aspect, the method further includes analyzing the digital twin of the machine for, at least in part, the identification of the part of the machine.

In a related aspect, the method further includes analyzing the digital twin of the machine for identifying an area of vibration in relation to the machine.

In a related aspect, the method further includes analyzing the digital twin of the machine for determining a vibration effect in the area.

In a related aspect, the method further including recommending a second maintenance action based on the analysis of the digital twin of the machine and the second maintenance action being related to the area.

In a related aspect, the method further including analyzing the digital twin of the machine for determining resonance vibration in the area.

In a related aspect, the method further including detecting a digital twin simulated resonance pattern.

In a related aspect, the method further including recommending a third maintenance action based on the digital twin simulated resonance pattern.

In a related aspect, the method further including populating a historical knowledge corpus, at least in part, communicating with a cognitive system for the analysis of the acoustic data.

In another aspect according to the present invention, a system using a computer for detecting a machine maintenance action at a location using acoustic analysis of the machine to detect a probable maintenance action, includes a computer system. The computer system includes; a computer processor, a computer-readable storage medium, and program instructions stored on the computer-readable storage medium being executable by the processor, to cause the computer system to perform the following functions to; receive, at a computer, acoustic data from a plurality of microphones at a location, the microphones receiving sounds from a machine at the location; analyze the acoustic data with respect to a database of specifications for the machine, the analysis of the acoustic data includes correlating the acoustic data to the specifications of the machine stored in the database; determine when a first measured parameter for the machine as measured as part of the analysis of the acoustic data, is outside a first specification of the machine as part of the machine specifications as indicated in the database of specifications for the machine, indicating a first measurement variation from the first specification of the machine; assess when the first measurement variation outside the first specification indicates a problem, the assessing including identifying a part associated with the machine and causally related to the first measurement variation; assess the first measurement variation to determine a reason for the first measurement variation in relation to the identified part; and send an alert to a device with a recommendation or action regarding the identified part, based on the reason for the first measurement variation.

In a related aspect, the device can be another machine or the device is a first device of a human resource.

In a related aspect the recommendation or the action can be a maintenance action for the machine.

In a related aspect the part is a part of the machine, or the part is associated to the machine which includes a machine environment part being operatively communicating with the machine.

In a related aspect, the determining when the first measured specification for the machine being measured as part of the analysis of the acoustic data is a result, at least in part, of a digital twin simulation engine generating a digital twin of the machine.

In another aspect according to the present invention, a computer program product for detecting a machine maintenance action at a location using acoustic analysis of the machine to detect a probable maintenance action, and the computer program product includes a computer readable storage medium having program instructions embodied therewith. The program instructions are executable by a computer to cause the computer to perform functions, by the computer, comprising the functions to: receive, at a computer, acoustic data from a plurality of microphones at a location, the microphones receiving sounds from a machine at the location; analyze the acoustic data with respect to a database of specifications for the machine, the analysis of the acoustic data includes correlating the acoustic data to the specifications of the machine stored in the database; determine when a first measured parameter for the machine as measured as part of the analysis of the acoustic data, is outside a first specification of the machine as part of the machine specifications as indicated in the database of specifications for the machine, indicating a first measurement variation from the first specification of the machine; assess when the first measurement variation outside the first specification indicates a problem, the assessing including identifying a part associated with the machine and causally related to the first measurement variation; assess the first measurement variation to determine a reason for the first measurement variation in relation to the identified part; and send an alert to a device with a recommendation or action regarding the identified part, based on the reason for the first measurement variation.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. The drawings are discussed forthwith below.

FIG. 1 is a schematic block diagram illustrating an overview of a system, system features or components, and methodology for detecting a machine maintenance action at a location using acoustic analysis of the machine to detect a probable maintenance action, according to an embodiment of the present disclosure.

FIG. 2 is a flow chart illustrating a method, implemented using the system shown in FIG. 1, for detecting a machine maintenance action at a location using acoustic analysis of the machine to detect a probable maintenance action, according to an embodiment of the present disclosure.

FIG. 3A is another flow chart illustrating another method, implemented using the system shown in FIG. 1, for detecting a machine maintenance action at a location using acoustic analysis of the machine to detect a probable maintenance action, according to an embodiment of the present disclosure.

FIG. 3B is a continuation of the flow chart shown in FIG. 3A implemented using the system shown in FIG. 1.

FIG. 4 is a functional schematic block diagram showing a series of operations and functional methodologies, for instructional purposes illustrating functional features of the present disclosure associated with the embodiments shown in the FIGS., for detecting a machine maintenance action at a location using acoustic analysis of the machine to detect a probable maintenance action.

FIG. 5 is another functional schematic block diagram showing a series of operations and functional methodologies, for instructional purposes illustrating functional features of the present disclosure associated with the embodiments shown in the FIGS., for detecting a machine maintenance action at a location using acoustic analysis of the machine to detect a probable maintenance action.

FIG. 6 is a schematic block diagram depicting a computer system according to an embodiment of the disclosure which may be incorporated, all or in part, in one or more computers or devices shown in FIG. 1, and cooperates with the systems and methods shown in the FIGS.

FIG. 7 is a schematic block diagram of a system depicting system components interconnected using a bus. The components for use, in all or in part, with the embodiments of the present disclosure, in accordance with one or more embodiments of the present disclosure.

FIG. 8 is a block diagram depicting a cloud computing environment according to an embodiment of the present invention.

FIG. 9 is a block diagram depicting abstraction model layers according to an embodiment of the present invention.

### DETAILED DESCRIPTION

The following description with reference to the accompanying drawings is provided to assist in a comprehensive understanding of exemplary embodiments of the invention as defined by the claims and their equivalents. The description includes various specific details to assist in that understanding, but these are to be regarded as merely exemplary, and assist in providing clarity and conciseness. Accordingly, those of ordinary skill in the art will recognize that various changes and modifications of the embodiments described herein can be made without departing from the scope and spirit of the invention. In addition, descriptions of well-known functions and constructions may be omitted.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

As used herein, an item can include any object or thing which can resonance is a vibration of any object which is matching with its natural vibration frequency.

### EMBODIMENTS AND EXAMPLES

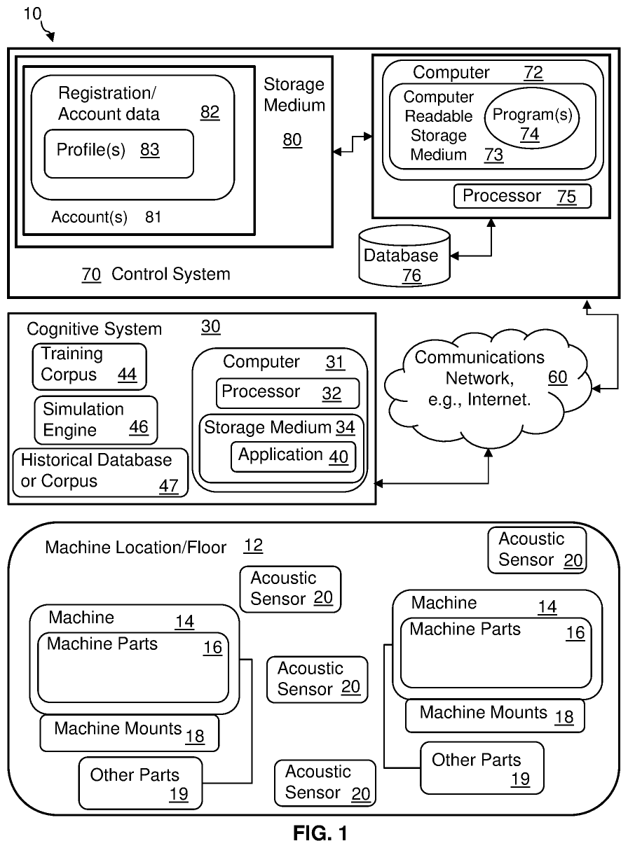

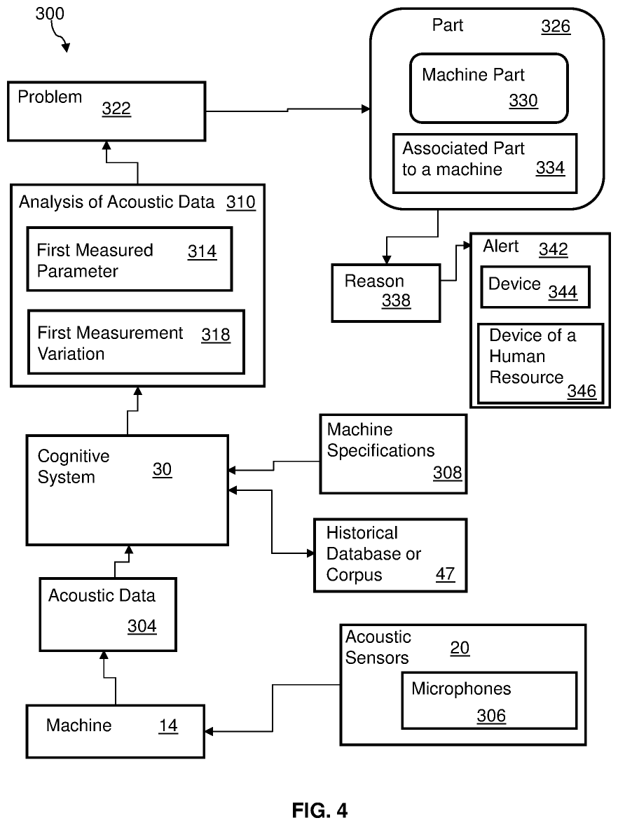

Referring to FIGS. 1 and 2, and FIG. 4 a computer-implemented method 100 for detecting a machine maintenance action at a location using acoustic analysis of the machine to detect a probable maintenance action, according to an embodiment of the present disclosure. The method 100 includes a series of operational blocks for implementing an embodiment according to the present disclosure which includes receiving, at a computer 31, as part of a cognitive system 30, acoustic data 304 (shown in FIG. 4), as in block 104. The cognitive system 30 can include the computer 31 which includes a storage medium 34 including an application 40, which can embody the present method, and a processor 32 for executing instructions of the application. The cognitive system 30 can also include a training corpus 44, simulation engine 46 and a historical database or corpus 47 which will be discussed in greater detail below. The cognitive system 30 can communicated with a control system 70 via a communications network 60, for example, the Internet.

The acoustic data 304 is received from a plurality of microphones 306 which are an embodiment of acoustic sensors 20 placed at a location 12. The location can be embodied as a machine shop or a shop floor, or any number of embodiments where machines are employed to conduct work. The microphones 306 receive sounds from a machine at the location, as also in block 104. In one example, one or more microphones can receive or detect sounds from one or more machines.

The method 100 includes analyzing the acoustic data with respect to a database of specifications for the machine, as in block 108. The analysis of the acoustic data includes correlating the acoustic data to the specifications of the machine stored in the database. For example, the database can be embodied as a historical database or corpus 47. The specifications of the machine or machine specifications 308 can include acoustic data specifications, as well as other specifications for maintenance and cooperation of the machine.

The method 100 includes determining when a first measured parameter 314 for the machine as measured as part of the analysis of the acoustic data, is outside a first specification of the machine as part of the machine specifications as indicated in the database of specifications for the machine, as in block 112. For example, a first measured parameter can be a measurement based on the acoustic data, for instance, a pitch of a sound the machine is making. In another example, a noise itself, such as a clunking, can indicate a problem is occurring with a part. The first measured specification being outside the first specification indicating a first measurement variation from the first specification of the machine, also as in block 112.

When a first measurement variation is not determined, the method returns to bock 108.

When a first measurement variation is determined, the method continues to block 120.

The method 100 includes assessing when the first measurement variation outside the first specification indicates a problem, as in block 120. Such an indication can include a negative variation, for example, the first measurement variation being off from machine specifications, or outside acceptable variances from a machine specification. The assessing can include identifying a part 326 associated to the machine and causally related to the first measurement variation, also as in block 120. For example, a part of the machine, or machine part 330, can be identified. In another example, a part associated with the machine, at block 334, can be identified, such as a mount, ventilation, duct work, electrical lines or leads, etc., connected to or otherwise operatively communicating with the machine. Any of the parts, alone or in combination, can be casually related to the measurement variation and thus the vibration.

When a variation does not indicate a problem in block 124, the method returns to block 120. When a variation indicates a problem in block 124, the method continues to block 128.

The method 100 includes assessing the first measurement variation to determine a reason 338 for the first measurement variation in relation to the identified part of the machine, as in block 128.

The method 100 includes sending an alert 342 to a device 344 with a recommendation or action regarding the identified part, based on the reason for the first measurement variation, as in block 132.

### OTHER EMBODIMENTS AND EXAMPLES

In one example, the device 344 can be another machine, or the device can be a first device of a human resource 346.

In another example, the recommendation or the action can be a maintenance action for the machine.

In another example, the analysis of the acoustic data can be generated at least in part by a cognitive system.

In another example the determining when the first measured specification for the machine being measured as part of the analysis of the acoustic data can be a result, at least in part, of a digital twin simulation engine generating a digital twin of the machine.

In another example, the method can further include analyzing the digital twin of the machine for, at least in part, the identification of the part of the machine.

In another example, the method can further include analyzing the digital twin of the machine for identifying an area of vibration in relation to the machine.

In another example, the method can further include analyzing the digital twin of the machine for determining a vibration effect in the area.

In another example, the method can further include recommending a second maintenance action based on the analysis of the digital twin of the machine and the second maintenance action being related to the area.

In another example, the method can further include analyzing the digital twin of the machine for determining resonance vibration in the area.

In another example, the method can further include detecting a digital twin simulated resonance pattern.

In another example, the method can include recommending a third maintenance action based on the digital twin simulated resonance pattern.

In another example, the method can further include populating a historical knowledge corpus, at least in part, communicating with a cognitive system for the analysis of the acoustic data.

### OTHER EMBODIMENTS AND EXAMPLES

In one example, the system of the present disclosure can include a control system 70 communicating with the cognitive system 30 via a communications network 60. The control system can incorporate all or part of an application or software for implementing the method of the present disclosure. The control system can include a computer readable storage medium 80 where account data and/or registration data 82 can be stored. User profiles 83 can be part of the account data and stored on the storage medium 80. The control system can include a computer 72 having computer readable storage medium 73 and software programs 74 stored therein. A process or 75 can be used to execute or implement the instructions of the software program. The control system can also include a database 76.

In examples, a user can include a company, a machine, an operator of a machine or someone responsible for a machine. A user can register or create an account using the control system 70 which can include one or more profiles 83 as part of registration and/or account data 82. The registration can include profiles for each user having personalized data. For example, users can register using a website via their computer and GUI (Graphical User Interface) interface. The registration or account data 82 can include profiles 83 for an account 81 for each user. Such accounts can be stored on the control system 70, which can also use the database 76 for data storage.

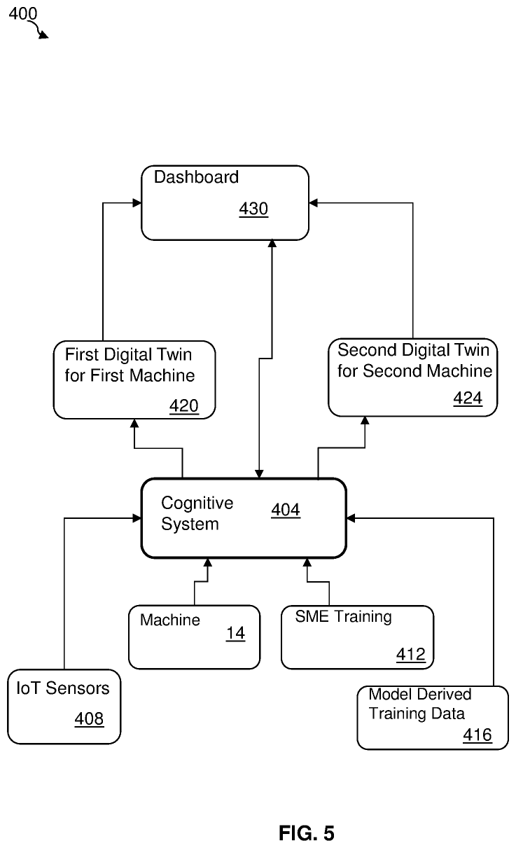

Additionally, the method and system is discussed with reference to FIGS. 4 and 5, which are functional systems which includes components and operations for embodiments according to the present disclosure, and are used herein for reference when describing the methods and systems of the present disclosure. Additionally, the functional systems, according to embodiments of the present disclosure, depict functional operation indicative of the embodiments discussed herein.

### FURTHER EMBODIMENTS AND EXAMPLES

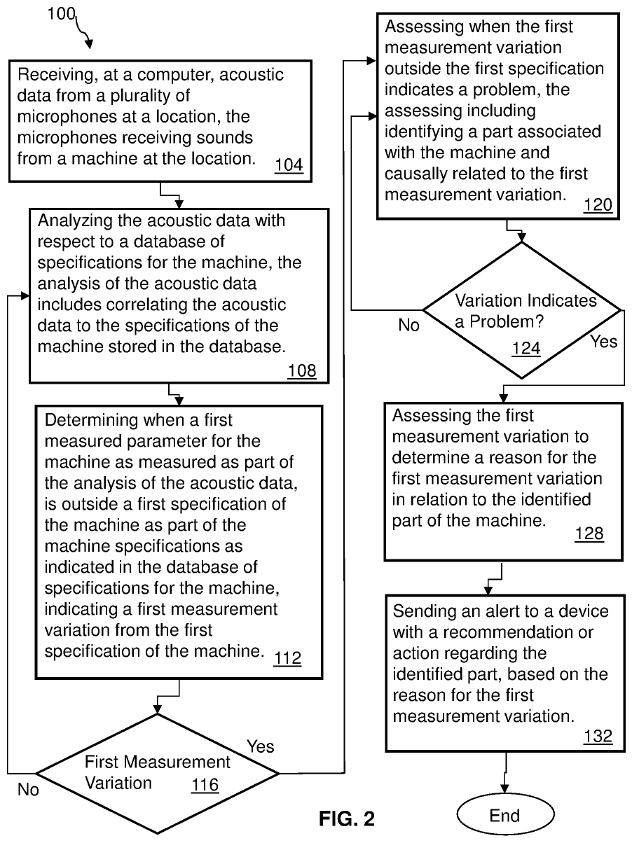

Operational blocks of the method 400 shown in FIG. 4 may be similar to operational blocks shown in FIGS. 1 and 2. The method shown in FIG. 4 is intended as another example embodiment which can include aspects/operations shown and discussed previously in the present disclosure.

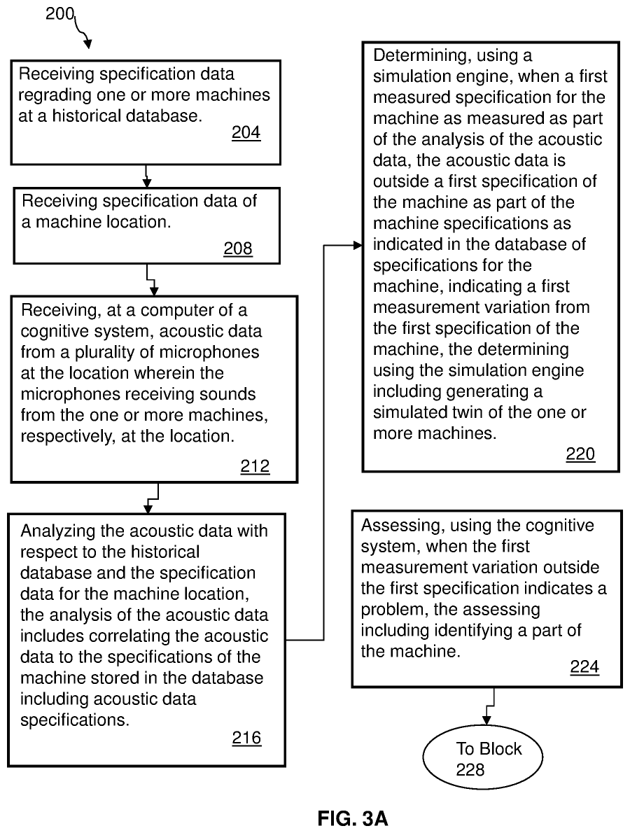

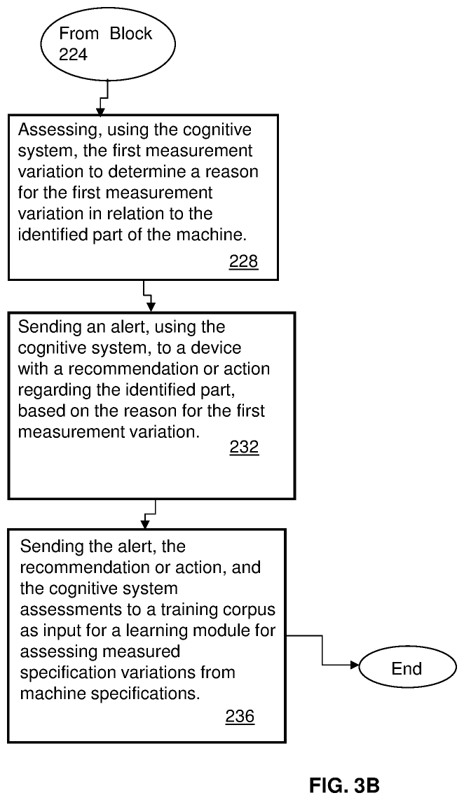

In another embodiment according to the present disclosure, referring to FIG. 3, a method 200 includes receiving specification data regarding one or more machines at a historical database, as in block 204.

The method 200 include receiving specification data of a machine location, that is, a machine shop floor layout, as in block 208. The specification data including part and items communicating with the machine, such as mounting parts and devices, duct work, power lines, ventilation, cooling devices and parts.

The method including receiving, at a computer of a cognitive system, acoustic data form a plurality of microphones at the location wherein the microphones receiving sounds from the one or more machines, respectively, at the location, as in block 212.

The method including analyzing the acoustic data with respect to the historical database and the specification data for the machine location, the analysis of the acoustic data includes correlating the acoustic data to the specifications of the machine stored in the database including acoustic data specifications, as in block 216.

The method 200 including determining, using a simulation engine, when a first measured specification for the machine as measured as part of the analysis of the acoustic data, the acoustic data is outside a first specification of the machine as part of the machine specifications as indicated in the database of specifications for the machine, indicating a first measurement variation from the first specification of the machine, as in block 220. The determining using the simulation engine including generating a simulated twin of the one or more machines, also as in block 220.

The method 200 including assessing, using the cognitive system, when the first measurement variation outside the first specification indicates a problem, the assessing including identifying a part of the machine, as in block 224.

The method including assessing, using the cognitive system, the first measurement variation to determine a reason for the first measurement variation in relation to the identified part of the machine, as in block 228.

The method including sending an alert, using the cognitive system, to a device with a recommendation or action regarding the identified part, based on the reason for the first measurement variation, as in block 232.

The method including sending the alert, the recommendation or action, and the cognitive system assessments, including the assessments of blocks 224 and 228, to a training corpus as input for a learning module for assessing measured specification variations from machine specifications, as in block 236.

### OTHER EMBODIMENTS AND EXAMPLES

The present disclosure is directed towards a method and system for prioritizing one or more areas in a production line for performing reactive/preventive maintenance on one or more damaged machine parts based on a predicted degree of damages/resonance frequency in a machine using digital twin simulation. More specifically, the method and system can include identifying one or more sources, pattern and type of vibration/wave propagation in one or more machine parts, ground structure and the like based on analysis of sensor feed, acoustic feed and historical corpus. The method and system can include determining one or more causes, degree and consequences of identified vibration/wave propagation in the machine parts and resonance frequency based on digital twin simulation on a plurality of conditions/loads by creating a digital twin model for each and every assets of the machine. The method and system can include prioritizing one or more area in the machine for performing an appropriate reactive/preventive maintenance action based on the determined degree, causes, consequence and resonance frequency of identified vibration/wave propagation in the machine.

The present disclosure includes prioritizing one or more areas in a machine for performing an appropriate reactive/preventive maintenance action based on a determined degree, causes, consequence and resonance frequency of identified vibration/wave propagation in the machine.

It is understood that resonance is a vibration of any object which is matching with its natural vibration frequency. In one example, vibration can be generated in machine, whereas resonance can happen in a connected pipeline. Embodiments of the present disclosure can consider entire machine ecosystem, and generate digital twin operation of each of the machines and associated connections such as pipes, tubes, wiring conduits. Embodiments can identify where resonance will be created, and will be causing maximum damage, and accordingly prioritizing the maintenance activity across the system.

The digital twin of all of the active equipment (machines and other powered devices) and passive equipment with linkages in the operational mode is available and the data from the digital twins can be treated as equal with live data under current operating conditions.

In embodiments of the present disclosure, based on the frequencies measured, the digital twin uses it to check if any of these could contribute to positive energy build up that can lead to a resonance condition and identifies the components that produce the triggering frequency (which will not be a resonance frequency of the generating machine) that will lead to a resonance condition in the future especially in the passive components in the system.

In another example in accordance with the present disclosure, a system that uses the digital twins output of the systems and their components frequencies for determining if there can be potential relationships in such data that indicate a future resonance condition, and shows if some of the passive components have undergone some degradation to their properties that would need active maintenance intervention.

In another example in accordance with embodiments of the present disclosure, the digital twin models for all active and passive but connected elements in the area are available such that the frequencies expected as shown by the digital twin and the measured frequencies can be matched.

In another example, the models of the machines to be made such that the energy expelled in the vibrations by one machine and possible energy absorptions by the passive and active components at multiple and sub-multiples of any resonance frequencies that can cause a future resonance frequency build up is shown. The models to incorporate how such energy is additive based on the phase delays and can cause the build up to resonance. The models to also incorporate the appropriate methods to determine from the vibration changes, which machines or passive components may have some changes to their system properties causing such a change in the frequency and energy and if this change can change further leading to an increase to the point of triggering a resonance vibration and causing an emergency maintenance requirement.

In another example, embodiments of the present disclosure can include automatic changes to the resonance vibration models due to changes detected in the vibration and energy measurements.

In another example, the AI system can take such energy and frequency inputs and determine if any of the components is undergoing degradation (such as loosening of screws, connectors and clamps changing position that the start vibrating more and loosening up in the future) and identify them for maintenance requests before they become emergency maintenance requests.

In another example, embodiments of the present disclosure can include a model of the structure composed of all interconnected systems wherein based on the vibrations measured and the inputs of operation being provided. Such a model can compute the vibration frequency for each component in the loops and sub-loops of operations. As an example, an insect is clawing into the wood in a cabinet and creates the sound causing the cabinet to vibrate and this vibration is carried to an attached shelf that is fitted also to the wall. In such an example, the method and system can model that such vibrations falls into the resonance range to cause the shelf clamp to become loose and shelf to tilt or fall off. In another example, the method and system can include measuring the vibration and feed this data into the model to be able to show that it contains the vibrations in near resonance conditions of the cabinet and the shelf loop.

Embodiments of the present disclosure can include providing information before or when the vibration information is provided, to show the frequency loops or subloops which are moving towards resonance when positive feedback of the vibrations can impact the structures.

In another example, embodiments of the present disclosure can include resonance frequencies of any equipment either individually or in relation with passive components. In another example, systems and methods according to the present disclosure can include a digital twin showing the resonant frequencies and the solution measuring vibrations or acoustic signals from the running machines. In another example, a model can include energy spread by the vibrations and computing how this can combine with the vibration energy in other components—active/passive to determine if any of them will reach their resonance frequencies. In another example, the method and system can include work scope to include both active and passive components that have to be addressed in the maintenance. In another example, the work scope order can show maintenance issues due to resonance possibilities in the active and passive equipment.

Embodiment in accordance with the present disclosure includes proposing a method and system to identify how the vibration is propagated from one location to another location, and if the propagated vibration is creating resonance if any portion of the propagated path, and accordingly with digital twin simulation identifying which area will be having damages and recommending the maintenance prioritization.

### ADDITIONAL EMBODIMENTS AND EXAMPLES

Embodiments of the present disclosure can include a method and system by which an analysis based on an IoT feed, acoustic feed, and doppler test can be performed on the propagated vibration or wave generated from different machines, ground, structure, etc. Such vibration can be because of any loose-fitting in moving parts. And the analysis can be used to identify the source of vibration, criticality of the vibration, and accordingly predict the priority of rectification so that damages can be prevented. The cognitive component to which these measured inputs are fed, will determine if there is a potential for a breakdown as the combinations of possible scenarios incorporates both the theoretical values as well as practical experiential values in the training corpus.

Some of the benefits of the embodiments of the present disclosure can include optimizing asset health by understanding equipment needs. Another benefit includes predicting asset failure and avoiding unforeseen machine failures. Another benefit can include extending the useful life of assets. Other benefits can include prioritizing repairs and replacements, and improving asset strategy and asset management processes.

In one example, machines are placed in various places, like in a shop floor, which can include mining machines, etc. The machines can be used for different purposes, and the machines are mounted on a structure, apart from machine. Further, there are some non-machine items like pipes, and the pipes are connected with joins etc. If there is a loose-fitting on any mounting, or in any machine parts, then it creates vibration, the created vibration can propagate through the machine parts. If there is a loose-fitting, or improper coupling in the machine parts or differential aging rates across components, then it creates vibration, and noise. The created vibration propagates through the machine, body of machine, ground where it is mounted, or propagate to connectors, like pipe etc., and if the propagated vibration matches to natural frequency or multiples on the propagation path then resonance will be created, and this may cause major damage.

For example, damages in a machine, structure, pipes, etc., because of loose-fitting etc., can be dependent on various factors, for instance, if the created vibration matches the natural frequency, will create resonance frequency, which can result in more damages. Another factor includes locating a loose-fitting. Another factor can include a vibration created in a water pipe, resulting in uneven force distribution, which may cause a stress fracture or crack in a structure such as a water pipe. In another example, a loose-fitting may not create any critical vibration, and can be addressed with a lower priority.

Several of the serious system conditions may occur in combinations of the frequency loops, or due to several factors that are not captured. Embodiments of the present disclosure provide a method and system for tracking a vibration propagation pattern and predicting a degree of damages because of vibration propagation. The method and system can prioritize an area where preventive or reactive maintenance is to be performed. The method and system can include a cognitive solution which can be run when acoustic feeds, i.e., acoustic inputs to the system, when analyzed point to a variation. The present methods and systems provide more authentic information whether a potential breakdown situation may arise.

Using IoT, acoustic feed analysis along with historical knowledge corpus, embodiments according to the present disclosure can identify the sources of vibration in any machine part or in the associated ecosystem (like pipe line assembly, structural mounting, etc.), ground structure etc., and accordingly be prioritizing the sources of vibration in the surrounding based on predicted changes of reaching at resonance frequency in the said machine, machine parts, ground, pipeline etc. (in the entire connected ecosystem). A digital twin simulation engine can show an area surrounding a machine which might be reach at a resonance frequency. Based on the types and pattern of vibration and propagation of vibration, including acoustic feed, etc., a cognitive system can classify the vibration to understand if the source of vibration is because of loose-fitting or unbalance force distribution, propagation of vibration from any other system, like flow of fluid through a pipe, and accordingly the digital twin computing system can simulate causes of vibration and the potential area where resonance will occur.

A digital twin simulation engine can simulate types of problems or accidents which might take place if proper action is not taken at the sources of vibration or any area in the ecosystem where resonance is created. The digital twin simulation engine can create the consequences of damages to the machines or any part of the ecosystem.

A digital twin computing system can track the types of vibration, vibration propagation path, movement of vibration from one media to another media, (for example, machine to machine, machine to pipeline, other associated systems) presence of a damping unit, etc. Accordingly, the computing system can simulate the duration of resonance in the ecosystem, and can notify to perform appropriate corrective action (maintenance, reduce load, increase spring constant, etc.) in the ecosystem where the duration of resonance is more than a threshold limit of time.

A digital twin simulation engine with a cognitive system can prioritize a loose-fitting or unbalance force distribution-based vibration, or problem in a damping system, so that appropriate action can be taken for preventive or mitigation in the ecosystem where it is applicable. Based on a digital twin simulated resonance pattern, duration of resonance for any particular activities, the digital twin computing system can recommend how a spring constant can be increased so that range of natural frequency can be increased and can avoid resonance situation. To increase a spring constant, additional load or stiffness can be increased.

Referring to FIG. 5, a digital twin computing system 400 can simulate a multi-asset ecosystem, and can simulate how a loose fitting or unbalance force distribution is created in different areas and causing vibration. The system 400 can also simulate how the resultant vibration might create resonance frequency and create damage or quality issue, and accordingly be prioritizing the area to be rectified.

Continuing with reference to FIG. 5, in a multi-asset ecosystem like a machine shop floor, engineering field etc., multiple IoT sensors can be placed in different places, and at the same time, a microphone can also be used for gathering acoustic signals. As per a specification of a machine, moving parts, static structure, the system 400 can capture the dimension, material property, mass, etc., can be captured, and the same will be stored against each of the machine parts. A digital twin computing system embodied as a cognitive system 404 can identifying each and every machine parts, bill of materials (BoM) and accordingly create digital twin models of each and every assets, for example, first digital twin for a first machine, and second digital twin for a second machine. The digital twin computing system 404 can also gather the material properties, length etc., and based on a natural frequency of different machine parts be identified. The cognitive system 404 can be fed, or receive an input of, the natural frequencies of different machines under different loads and multi-system loops with the auxiliary equipment. The system 404 can be trained with subject matter knowledge of potential combinations that can build up over different time scales to a breakdown. The proposed system will also be gathering the sensor feed from various portions of machines, ground, etc. Apart from the sensor feed, the proposed system will also gather acoustic feed (that is, acoustic input) from different microphones installed in the surrounding area of the machine. The system 404 can receive the sensor feed to track if the actual vibration is closed to resonance frequency.

IoT input and acoustic input from different surroundings can track how the vibrations are propagating and how the vibrations are propagating from one media to another media and creating sound. Based on the sensor feeds the proposed cognitive system will be identifying the vibration propagation pattern and with Doppler effect the proposed system will be identifying the sources of vibration and providing the frequencies measured that can cause a breakdown. The digital twin simulation model can simulate the entire multi-asset ecosystem and can simulate the vibration propagation in the digital twin model. While creating vibration simulation with digital twin model, the proposed system will be considering entire ecosystem, like, mounted ground, structure, static or moving objects, etc. The IoT enabled system will also be tracking the wear and tear with the machine, moving parts etc., and accordingly be identifying any shift in the weight distribution and if the weight distribution is creating any unbalance force. The digital twin simulation system will also be identifying the change in alignment of the machine parts and accordingly can identify if the alignment will be creating any quality in the work product. The digital twin computing system can consider the vibration pattern, vibration propagation in different structural positions, and with Doppler effect calculation, the sources of vibration can be identified. Based on identified sources of vibration, the digital twin computing system can identify which sources of vibration are causing resonance frequency and creating quality problems. Based on the identified areas where resonance frequencies are occurring, areas can accordingly be identified which are having structural problems, or can have quality problems in the work product. The digital twin simulation engine can prioritize the area where preventive maintenance is required so that predicted damages or quality can be addressed. The digital twin computing system can specifying the areas around the multi-asset ecosystem where preventive maintenance is required. The digital twin computing system can identify the areas where unbalances force is created and accordingly show how the unbalance forces are creating vibration. The digital twin model can prioritize the unbalance force distribution where corrective action is to be taken.

### FURTHER EMBODIMENTS AND EXAMPLES

Account data, for instance, including profile data related to a user, and any data, personal or otherwise, can be collected and stored, for example, in the control system 70. It is understood that such data collection is done with the knowledge and consent of a user, and stored to preserve privacy, which is discussed in more detail below. Such data can include personal data, and data regarding personal items.

In one example a user can register 82 have an account 81 with a user profile 83 on a control system 70, which is discussed in more detail below. For example, data can be collected using techniques as discussed above, for example, using cameras, and data can be uploaded to a user profile by the user.

### MORE EXAMPLES AND EMBODIMENTS

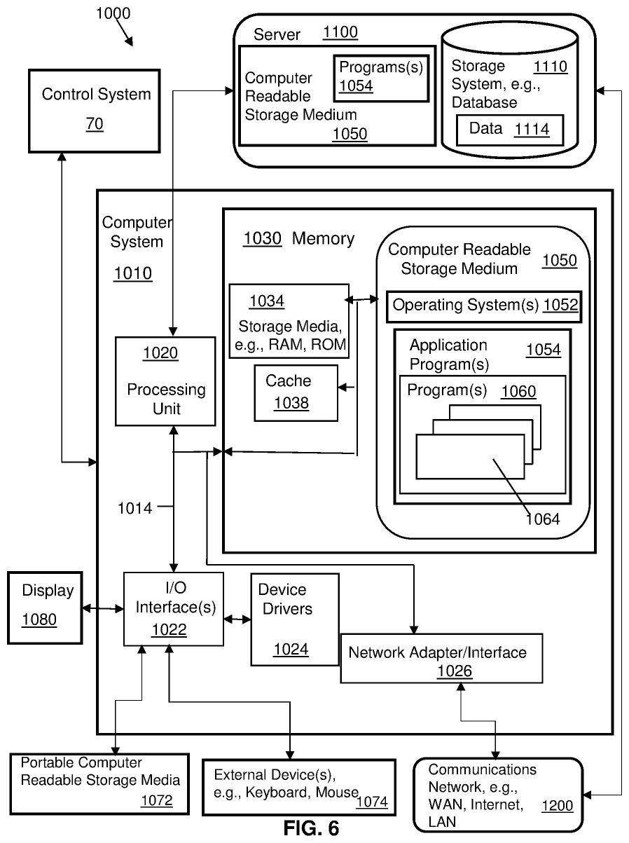

In the embodiment of the present disclosure shown in FIGS. 1 and 2, a computer can be part of a remote computer or a remote server, for example, remote server 1100 (FIG. 6). In another example, the computer 72 can be part of a control system 70 and provide execution of the functions of the present disclosure. In another embodiment, a computer can be part of a mobile device and provide execution of the functions of the present disclosure. In still another embodiment, parts of the execution of functions of the present disclosure can be shared between the control system computer and the mobile device computer, for example, the control system function as a back end of a program or programs embodying the present disclosure and the mobile device computer functioning as a front end of the program or programs.

The computer can be part of the mobile device, or a remote computer communicating with the mobile device. In another example, a mobile device and a remote computer can work in combination to implement the method of the present disclosure using stored program code or instructions to execute the features of the method(s) described herein. In one example, the cognitive system 30 can include a computer 31 having a processor 32 and a storage medium 34 which stores an application 40. The application can incorporate program instructions for executing the features of the present disclosure using the processor 32. In another example, the mobile device application or computer software can have program instructions executable for a front end of a software application incorporating the features of the method of the present disclosure in program instructions, while a back end program or programs 74, of the software application, stored on the computer 72 of the control system 70 communicates with the mobile device computer and executes other features of the method. The control system 70 and the cognitive system 30 can communicate using a communications network 60, for example, the Internet.

Thereby, the method 100 according to an embodiment of the present disclosure, can be incorporated in one or more computer programs or an application 40 stored on an electronic storage medium 34, and executable by the processor 32, as part of the computer on the mobile device. For example, a mobile device can communicate with the control system 70, and in another example, a device such as a video feed device can communicate directly with the control system 70. Other users (not shown) may have similar mobile devices which communicate with the control system similarly. The application can be stored, all or in part, on a computer or a computer in a mobile device and at a control system communicating with the mobile device, for example, using the communications network 60, such as the Internet. It is envisioned that the application can access all or part of program instructions to implement the method of the present disclosure. The program or application can communicate with a remote computer system via a communications network 60 (e.g., the Internet) and access data, and cooperate with program(s) stored on the remote computer system. Such interactions and mechanisms are described in further detail herein and referred to regarding components of a computer system, such as computer readable storage media, which are shown in one embodiment in FIG. 6 and described in more detail in regards thereto referring to one or more computer systems 1010.

Thus, in one example, a control system 70 is in communication with the computer 31, and the computer can include the application or software 40. The computer 31, or a computer in a mobile device (not shown) communicates with the control system 70 using the communications network 60.

In another example, the control system 70 can have a front-end computer belonging to one or more users, and a back-end computer embodied as the control system.

Also, referring to FIG. 1, a device or cognitive system 30 can include a computer 31, computer readable storage medium 34, and operating systems, and/or programs, and/or a software application 40, which can include program instructions executable using a processor 32. These features are shown herein in FIG. 1, and also in an embodiment of a computer system shown in FIG. 6 referring to one or more computer systems 1010, which may include one or more generic computer components.

The method according to the present disclosure, can include a computer for implementing the features of the method, according to the present disclosure, as part of a control system. In another example, a computer as part of a control system can work in corporation with a mobile device computer in concert with communication system for implementing the features of the method according to the present disclosure. In another example, a computer for implementing the features of the method can be part of a mobile device and thus implement the method locally.

Specifically, regarding the control system 70, a device(s) or a cognitive system 30, or in one example the devices which can belong to one or more users, can be in communication with the control system 70 via the communications network 60. In the embodiment of the control system shown in FIG. 1, the control system 70 includes a computer 72 having a database 76 and one or more programs 74 stored on a computer readable storage medium 73. In the embodiment of the disclosure shown in FIG. 1, the device 30 communicates with the control system 70 and the one or more programs 74 stored on a computer readable storage medium 73. The control system includes the computer 72 having a processor 75, which also has access to the database 76.

The control system 70 can include a storage medium 80 for maintaining a registration 82 of users and their devices for analysis of the audio input. Such registration can include user profiles 83, which can include user data supplied by the users in reference to registering and setting-up an account. In an embodiment, the method and system which incorporates the present disclosure includes the control system (generally referred to as the back-end) in combination and cooperation with a front end of the method and system, which can be the application 40. In one example, the application 40 is stored on a device, for example, a computer on location, and can access data and additional programs at a back end of the application, e.g., control system 70.

The control system can also be part of a software application implementation, and/or represent a software application having a front-end user part and a back-end part providing functionality. In an embodiment, the method and system which incorporates the present disclosure includes the control system (which can be generally referred to as the back-end of the software application which incorporates a part of the method and system of an embodiment of the present application) in combination and cooperation with a front end of the software application incorporating another part of the method and system of the present application at the device, as in the example shown in FIG. 1 of a control system 30 and computer 31 having the application 40. The application 40 is stored on the computer 31 and can access data and additional programs at the back end of the application, for example, in the program(s) 74 stored in the control system 70.

The program(s) 74 can include, all or in part, a series of executable steps for implementing the method of the present disclosure. A program, incorporating the present method, can be all or in part stored in the computer readable storage medium on the control system or, in all or in part, on a computer 31 or device. It is envisioned that the control system 70 can not only store the profile of users, but in one embodiment, can interact with a website for viewing on a display of a device such as a mobile device, or in another example the Internet, and receive user input related to the method and system of the present disclosure. It is understood that FIG. 1 depicts one or more profiles 83, however, the method can include multiple profiles, users, registrations, etc. It is envisioned that a plurality of users or a group of users can register and provide profiles using the control system for use according to the method and system of the present disclosure.

### STILL FURTHER EMBODIMENTS AND EXAMPLES

It is understood that the features shown in some of the FIGS., for example block diagrams, are functional representations of features of the present disclosure. Such features are shown in embodiments of the systems and methods of the present disclosure for illustrative purposes to clarify the functionality of features of the present disclosure.

The methods and systems of the present disclosure can include a series of operation blocks for implementing one or more embodiments according to the present disclosure. In some examples, operational blocks of one or more FIGS. may be similar to operational blocks another FIG. A method shown in one FIG. may be another example embodiment which can include aspects/operations shown in another FIG. and discussed previously.

### ADDITIONAL EMBODIMENTS AND EXAMPLES

Regarding collection of data with respect to the present disclosure, such uploading or generation of profiles is voluntary by the one or more users, and thus initiated by and with the approval of a user. Thereby, a user can opt-in to establishing an account having a profile according to the present disclosure. Similarly, data received by the system or inputted or received as an input is voluntary by one or more users, and thus initiated by and with the approval of the user. Thereby, a user can opt-in to input data according to the present disclosure. Such user approval also includes a user's option to cancel such profile or account, and/or input of data, and thus opt-out, at the user's discretion, of capturing communications and data. Further, any data stored or collected is understood to be intended to be securely stored and unavailable without authorization by the user, and not available to the public and/or unauthorized users. Such stored data is understood to be deleted at the request of the user and deleted in a secure manner. Also, any use of such stored data is understood to be, according to the present disclosure, only with the user's authorization and consent.

In one or more embodiments of the present invention, a user(s) can opt-in or register with a control system, voluntarily providing data and/or information in the process, with the user's consent and authorization, where the data is stored and used in the one or more methods of the present disclosure. Also, a user(s) can register one or more user electronic devices for use with the one or more methods and systems according to the present disclosure. As part of a registration, a user can also identify and authorize access to one or more activities or other systems (e.g., audio and/or video systems). Such opt-in of registration and authorizing collection and/or storage of data is voluntary and a user may request deletion of data (including a profile and/or profile data), un-registering, and/or opt-out of any registration. It is understood that such opting-out includes disposal of all data in a secure manner. A user interface can also allow a user or an individual to remove all their historical data.

### OTHER ADDITIONAL EMBODIMENTS AND EXAMPLES

In one example, Artificial Intelligence (AI) can be used, all or in part, for a learning model for analyzing data associated with items and assets.

In another example, the control system 70 can be all or part of an Artificial Intelligence (AI) system. For example, the control system can be one or more components of an AI system.

It is also understood that the method 100 according to an embodiment of the present disclosure, can be incorporated into (Artificial Intelligence) AI devices, which can communicate with respective AI systems, and respective AI system platforms. Thereby, such programs or an application incorporating the method of the present disclosure, as discussed above, can be part of an AI system. In one embodiment according to the present invention, it is envisioned that the control system can communicate with an AI system, or in another example can be part of an AI system. The control system can also represent a software application having a front-end user part and a back-end part providing functionality, which can in one or more examples, interact with, encompass, or be part of larger systems, such as an AI system. In one example, an AI device can be associated with an AI system, which can be all or in part, a control system and/or a content delivery system, and be remote from an AI device. Such an AI system can be represented by one or more servers storing programs on computer readable medium which can communicate with one or more AI devices. The AI system can communicate with the control system, and in one or more embodiments, the control system can be all or part of the AI system or vice versa.

It is understood that as discussed herein, a download or downloadable data can be initiated using a voice command or using a mouse, touch screen, etc. In such examples a mobile device can be user initiated, or an AI device can be used with consent and permission of users. Other examples of AI devices include devices which include a microphone, speaker, and can access a cellular network or mobile network, a communications network, or the Internet, for example, a vehicle having a computer and having cellular or satellite communications, or in another example, IoT (Internet of Things) devices, such as appliances, having cellular network or Internet access.

### FURTHER DISCUSSION REGARDING EXAMPLES AND EMBODIMENTS

It is understood that a set or group is a collection of distinct objects or elements. The objects or elements that make up a set or group can be anything, for example, numbers, letters of the alphabet, other sets, a number of people or users, and so on. It is further understood that a set or group can be one element, for example, one thing or a number, in other words, a set of one element, for example, one or more users or people or participants.

The descriptions of the various embodiments of the present invention have been presented for purposes of illustration, but are not intended to be exhaustive or limited to the embodiments disclosed. Likewise, examples of features or functionality of the embodiments of the disclosure described herein, whether used in the description of a particular embodiment, or listed as examples, are not intended to limit the embodiments of the disclosure described herein, or limit the disclosure to the examples described herein. Such examples are intended to be examples or exemplary, and non-exhaustive. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### FURTHER ADDITIONAL EXAMPLES AND EMBODIMENTS

Referring to FIG. 6, an embodiment of system or computer environment 1000, according to the present disclosure, includes a computer system 1010 shown in the form of a generic computing device. The method 100, for example, may be embodied in a program 1060, including program instructions, embodied on a computer readable storage device, or a computer readable storage medium, for example, generally referred to as computer memory 1030 and more specifically, computer readable storage medium 1050. Such memory and/or computer readable storage media includes non-volatile memory or non-volatile storage, also known and referred to non-transient computer readable storage media, or non-transitory computer readable storage media. For example, such non-volatile memory can also be disk storage devices, including one or more hard drives. For example, memory 1030 can include storage media 1034 such as RAM (Random Access Memory) or ROM (Read Only Memory), and cache memory 1038. The program 1060 is executable by the processor 1020 of the computer system 1010 (to execute program steps, code, or program code). Additional data storage may also be embodied as a database 1110 which includes data 1114. The computer system 1010 and the program 1060 are generic representations of a computer and program that may be local to a user, or provided as a remote service (for example, as a cloud based service), and may be provided in further examples, using a website accessible using the communications network 1200 (e.g., interacting with a network, the Internet, or cloud services). It is understood that the computer system 1010 also generically represents herein a computer device or a computer included in a device, such as a laptop or desktop computer, etc., or one or more servers, alone or as part of a datacenter. The computer system can include a network adapter/interface 1026, and an input/output (I/O) interface(s) 1022. The I/O interface 1022 allows for input and output of data with an external device 1074 that may be connected to the computer system. The network adapter/interface 1026 may provide communications between the computer system a network generically shown as the communications network 1200.

The computer 1010 may be described in the general context of computer system-executable instructions, such as program modules, being executed by a computer system. Generally, program modules may include routines, programs, objects, components, logic, data structures, and so on that perform particular tasks or implement particular abstract data types. The method steps and system components and techniques may be embodied in modules of the program 1060 for performing the tasks of each of the steps of the method and system. The modules are generically represented in the figure as program modules 1064. The program 1060 and program modules 1064 can execute specific steps, routines, sub-routines, instructions or code, of the program.

The method of the present disclosure can be run locally on a device such as a mobile device, or can be run a service, for instance, on the server 1100 which may be remote and can be accessed using the communications network 1200. The program or executable instructions may also be offered as a service by a provider. The computer 1010 may be practiced in a distributed cloud computing environment where tasks are performed by remote processing devices that are linked through a communications network 1200. In a distributed cloud computing environment, program modules may be located in both local and remote computer system storage media including memory storage devices.

More specifically, the system or computer environment 1000 includes the computer system 1010 shown in the form of a general-purpose computing device with illustrative periphery devices. The components of the computer system 1010 may include, but are not limited to, one or more processors or processing units 1020, a system memory 1030, and a bus 1014 that couples various system components including system memory 1030 to processor 1020.

The bus 1014 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

The computer 1010 can include a variety of computer readable media. Such media may be any available media that is accessible by the computer 1010 (e.g., computer system, or server), and can include both volatile and non-volatile media, as well as, removable and non-removable media. Computer memory 1030 can include additional computer readable media in the form of volatile memory, such as random access memory (RAM) 1034, and/or cache memory 1038. The computer 1010 may further include other removable/non-removable, volatile/non-volatile computer storage media, in one example, portable computer readable storage media 1072. In one embodiment, the computer readable storage medium 1050 can be provided for reading from and writing to a non-removable, non-volatile magnetic media. The computer readable storage medium 1050 can be embodied, for example, as a hard drive. Additional memory and data storage can be provided, for example, as the storage system 1110 (e.g., a database) for storing data 1114 and communicating with the processing unit 1020. The database can be stored on or be part of a server 1100. Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 1014 by one or more data media interfaces. As will be further depicted and described below, memory 1030 may include at least one program product which can include one or more program modules that are configured to carry out the functions of embodiments of the present invention.

The method(s) described in the present disclosure, for example, may be embodied in one or more computer programs, generically referred to as a program 1060 and can be stored in memory 1030 in the computer readable storage medium 1050. The program 1060 can include program modules 1064. The program modules 1064 can generally carry out functions and/or methodologies of embodiments of the invention as described herein. The one or more programs 1060 are stored in memory 1030 and are executable by the processing unit 1020. By way of example, the memory 1030 may store an operating system 1052, one or more application programs 1054, other program modules, and program data on the computer readable storage medium 1050. It is understood that the program 1060, and the operating system 1052 and the application program(s) 1054 stored on the computer readable storage medium 1050 are similarly executable by the processing unit 1020. It is also understood that the application 1054 and program(s) 1060 are shown generically, and can include all of, or be part of, one or more applications and program discussed in the present disclosure, or vice versa, that is, the application 1054 and program 1060 can be all or part of one or more applications or programs which are discussed in the present disclosure. It is also understood that a control system 70, communicating with a computer system, can include all or part of the computer system 1010 and its components, and/or the control system can communicate with all or part of the computer system 1010 and its components as a remote computer system, to achieve the control system functions described in the present disclosure. The control system function, for example, can include storing, processing, and executing software instructions to perform the functions of the present disclosure. It is also understood that the one or more computers or computer systems shown in FIG. 1 similarly can include all or part of the computer system 1010 and its components, and/or the one or more computers can communicate with all or part of the computer system 1010 and its components as a remote computer system, to achieve the computer functions described in the present disclosure.

In an embodiment according to the present disclosure, one or more programs can be stored in one or more computer readable storage media such that a program is embodied and/or encoded in a computer readable storage medium. In one example, the stored program can include program instructions for execution by a processor, or a computer system having a processor, to perform a method or cause the computer system to perform one or more functions. For example, in one embedment according to the present disclosure, a program embodying a method is embodied in, or encoded in, a computer readable storage medium, which includes and is defined as, a non-transient or non-transitory computer readable storage medium. Thus, embodiments or examples according to the present disclosure, of a computer readable storage medium do not include a signal, and embodiments can include one or more non-transient or non-transitory computer readable storage mediums. Thereby, in one example, a program can be recorded on a computer readable storage medium and become structurally and functionally interrelated to the medium.

The computer 1010 may also communicate with one or more external devices 1074 such as a keyboard, a pointing device, a display 1080, etc.; one or more devices that enable a user to interact with the computer 1010; and/or any devices (e.g., network card, modem, etc.) that enables the computer 1010 to communicate with one or more other computing devices. Such communication can occur via the Input/Output (I/O) interfaces 1022. Still yet, the computer 1010 can communicate with one or more networks 1200 such as a local area network (LAN), a general wide area network (WAN), and/or a public network (e.g., the Internet) via network adapter/interface 1026. As depicted, network adapter 1026 communicates with the other components of the computer 1010 via bus 1014. It should be understood that although not shown, other hardware and/or software components could be used in conjunction with the computer 1010. Examples, include, but are not limited to: microcode, device drivers 1024, redundant processing units, external disk drive arrays, RAID systems, tape drives, and data archival storage systems, etc.

It is understood that a computer or a program running on the computer 1010 may communicate with a server, embodied as the server 1100, via one or more communications networks, embodied as the communications network 1200. The communications network 1200 may include transmission media and network links which include, for example, wireless, wired, or optical fiber, and routers, firewalls, switches, and gateway computers. The communications network may include connections, such as wire, wireless communication links, or fiber optic cables. A communications network may represent a worldwide collection of networks and gateways, such as the Internet, that use various protocols to communicate with one another, such as Lightweight Directory Access Protocol (LDAP), Transport Control Protocol/Internet Protocol (TCP/IP), Hypertext Transport Protocol (HTTP), Wireless Application Protocol (WAP), etc. A network may also include a number of different types of networks, such as, for example, an intranet, a local area network (LAN), or a wide area network (WAN).

In one example, a computer can use a network which may access a website on the Web (World Wide Web) using the Internet. In one embodiment, a computer 1010, including a mobile device, can use a communications system or network 1200 which can include the Internet, or a public switched telephone network (PSTN) for example, a cellular network. The PSTN may include telephone lines, fiber optic cables, microwave transmission links, cellular networks, and communications satellites. The Internet may facilitate numerous searching and texting techniques, for example, using a cell phone or laptop computer to send queries to search engines via text messages (SMS), Multimedia Messaging Service (MMS) (related to SMS), email, or a web browser. The search engine can retrieve search results, that is, links to websites, documents, or other downloadable data that correspond to the query, and similarly, provide the search results to the user via the device as, for example, a web page of search results.

### STILL FURTHER ADDITIONAL EXAMPLES AND EMBODIMENTS

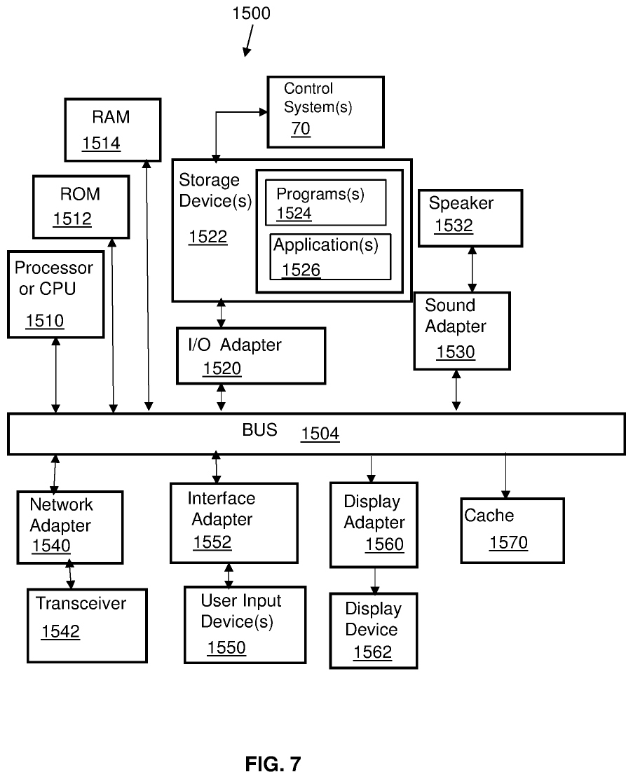

Referring to FIG. 7, an example system 1500 for use with the embodiments of the present disclosure is depicted. The system 1500 includes a plurality of components and elements connected via a system bus 1504 (also referred to as a bus). At least one processor (CPU) 1510, is connected to other components via the system bus 1504. A cache 1570, a Read Only Memory (ROM) 1512, a Random Access Memory (RAM) 1514, an input/output (I/O) adapter 1520, a sound adapter 1530, a network adapter 1540, a user interface adapter 1552, a display adapter 1560 and a display device 1562, are also operatively coupled to the system bus 1504 of the system 1500.

One or more storage devices 1522 are operatively coupled to the system bus 1504 by the I/O adapter 1520. The storage device 1522, for example, can be any of a disk storage device (e.g., a magnetic or optical disk storage device), a solid state magnetic device, and so forth. The storage device 1522 can be the same type of storage device or different types of storage devices. The storage device can include, for example, but not limited to, a hard drive or flash memory and be used to store one or more programs 1524 or applications 1526. The programs and applications are shown as generic components and are executable using the processor 1510. The program 1524 and/or application 1526 can include all of, or part of, programs or applications discussed in the present disclosure, as well vice versa, that is, the program 1524 and the application 1526 can be part of other applications or program discussed in the present disclosure. The storage device can communicate with the control system 70 which has various functions as described in the present disclosure.

A speaker 1532 is operatively coupled to system bus 1504 by the sound adapter 1530. A transceiver 1542 is operatively coupled to system bus 1504 by the network adapter 1540. A display 1562 is operatively coupled to the system bus 1504 by the display adapter 1560.

One or more user input devices 1550 are operatively coupled to the system bus 1504 by the user interface adapter 1552. The user input devices 1550 can be, for example, any of a keyboard, a mouse, a keypad, an image capture device, a motion sensing device, a microphone, a device incorporating the functionality of at least two of the preceding devices, and so forth. Other types of input devices can also be used, while maintaining the spirit of the present invention. The user input devices 1550 can be the same type of user input device or different types of user input devices. The user input devices 1550 are used to input and output information to and from the system 1500.

### OTHER ASPECTS AND EXAMPLES

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures of the present disclosure illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

### ADDITIONAL ASPECTS AND EXAMPLES

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based email). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

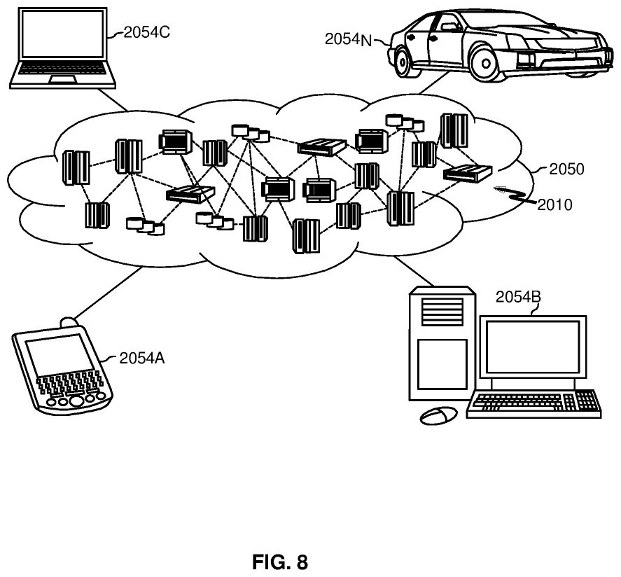

Referring now to FIG. 8, illustrative cloud computing environment 2050 is depicted. As shown, cloud computing environment 2050 includes one or more cloud computing nodes 2010 with which local computing devices used by cloud consumers, such as, for example, personal digital assistant (PDA) or cellular telephone 2054A, desktop computer 2054B, laptop computer 2054C, and/or automobile computer system 2054N may communicate. Nodes 2010 may communicate with one another. They may be grouped (not shown) physically or virtually, in one or more networks, such as Private, Community, Public, or Hybrid clouds as described hereinabove, or a combination thereof. This allows cloud computing environment 2050 to offer infrastructure, platforms and/or software as services for which a cloud consumer does not need to maintain resources on a local computing device. It is understood that the types of computing devices 2054A-N shown in FIG. 8 are intended to be illustrative only and that computing nodes 2010 and cloud computing environment 2050 can communicate with any type of computerized device over any type of network and/or network addressable connection (e.g., using a web browser).

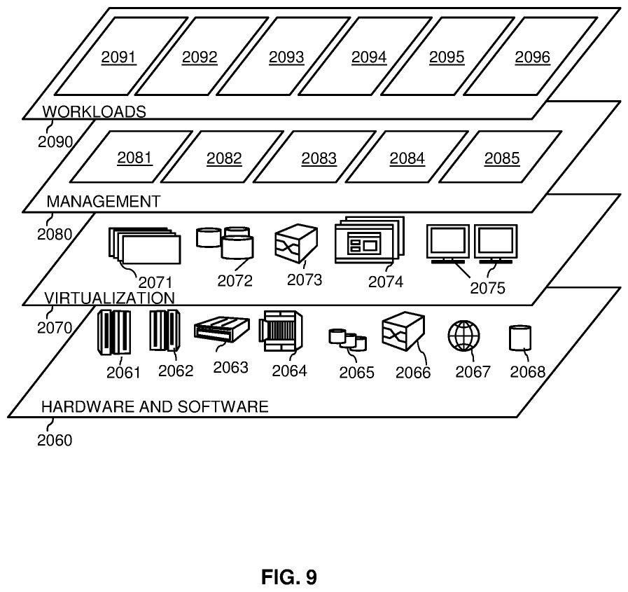

Referring now to FIG. 9, a set of functional abstraction layers provided by cloud computing environment 2050 (FIG. 8) is shown. It should be understood in advance that the components, layers, and functions shown in FIG. 9 are intended to be illustrative only and embodiments of the invention are not limited thereto. As depicted, the following layers and corresponding functions are provided:

Hardware and software layer 2060 includes hardware and software components. Examples of hardware components include: mainframes 2061; RISC (Reduced Instruction Set Computer) architecture based servers 2062; servers 2063; blade servers 2064; storage devices 2065; and networks and networking components 2066. In some embodiments, software components include network application server software 2067 and database software 2068.

Virtualization layer 2070 provides an abstraction layer from which the following examples of virtual entities may be provided: virtual servers 2071; virtual storage 2072; virtual networks 2073, including virtual private networks; virtual applications and operating systems 2074; and virtual clients 2075.

In one example, management layer 2080 may provide the functions described below. Resource provisioning 2081 provides dynamic procurement of computing resources and other resources that are utilized to perform tasks within the cloud computing environment. Metering and Pricing 2082 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 2083 provides access to the cloud computing environment for consumers and system administrators. Service level management 2084 provides cloud computing resource allocation and management such that required service levels are met. Service Level Agreement (SLA) planning and fulfillment 2085 provide pre-arrangement for, and procurement of, cloud computing resources for which a future requirement is anticipated in accordance with an SLA.

Workloads layer 2090 provides examples of functionality for which the cloud computing environment may be utilized. Examples of workloads and functions which may be provided from this layer include: mapping and navigation 2091; software development and lifecycle management 2092; virtual classroom education delivery 2093; data analytics processing 2094; transaction processing 2095; and acoustic analysis of sound data 2096, for example, using acoustic analysis of sound data from a machine to detect and identify vibration from the machine.

1. A method for detecting a machine maintenance action at a location using acoustic analysis of the machine to detect a probable maintenance action, comprising:
receiving, at a computer, acoustic data from a plurality of microphones at a location, the microphones receiving sounds from a machine at the location;
analyzing the acoustic data with respect to a database of specifications for the machine, the analysis of the acoustic data includes correlating the acoustic data to the specifications of the machine stored in the database, the specifications including acoustic data specifications, and specification for maintenance of the machine;
determining when a first measured parameter for the machine, as measured as part of the analysis of the acoustic data, is outside a first specification of the machine as part of the machine specifications as indicated in the database of specifications for the machine, indicating a first measurement variation from the first specification of the machine, wherein the first measured parameter is based on the acoustic data;
assessing when the first measurement variation outside the first specification indicates a problem, the assessing including identifying a part associated with the machine and causally related to the first measurement variation;
assessing the first measurement variation to determine a reason for the first measurement variation in relation to the identified part;
identifying, as at least part of the reason for the first measurement variation, one or more sources of vibration/wave propagation in one or more machine parts in relation to the machine, based on the first measured parameter for the machine being outside the first specification; and
sending an alert to a device with a recommendation or action regarding the identified part, based on the reason for the first measurement variation, and the recommendation or the action being at least in part, a maintenance action for the machine.

2. The method of claim 1, wherein the device is another machine or the device is a first device of a human resource.

3. (canceled)

4. The method of claim 1, wherein the part is a part of the machine, or the part is associated to the machine which includes a machine environment part operatively communicating with the machine.

5. The method of claim 1, wherein the analysis of the acoustic data is generated at least in part by a cognitive system.

6. The method of claim 5, wherein the determining when the first measured specification for the machine being measured as part of the analysis of the acoustic data is a result, at least in part, of a digital twin simulation engine generating a digital twin of the machine.

7. The method of claim 6, further comprising:
analyzing the digital twin of the machine for, at least in part, the identification of the part of the machine.

8. The method of claim 6, further comprising:
analyzing the digital twin of the machine for identifying an area of vibration in relation to the machine.

9. The method of claim 8, further comprising:
analyzing the digital twin of the machine for determining a vibration effect in the area.

10. The method of claim 9, further comprising:
recommending a second maintenance action based on the analysis of the digital twin of the machine and the second maintenance action being related to the area.

11. The method of claim 9, further comprising:
analyzing the digital twin of the machine for determining resonance vibration in the area.

12. The method of claim 9, further comprising:
detecting a digital twin simulated resonance pattern.

13. The method of claim 12, further comprising:
recommending a third maintenance action based on the digital twin simulated resonance pattern.

14. The method of claim 1, further comprising:
populating a historical knowledge corpus, at least in part, communicating with a cognitive system for the analysis of the acoustic data.

15. A system using a computer for detecting a machine maintenance action at a location using acoustic analysis of the machine to detect a probable maintenance action, which comprises:
a computer system comprising; a computer processor, a computer-readable storage medium, and program instructions stored on the computer-readable storage medium being executable by the processor, to cause the computer system to perform the following functions to;
receive, at a computer, acoustic data from a plurality of microphones at a location, the microphones receiving sounds from a machine at the location;
analyze the acoustic data with respect to a database of specifications for the machine, the analysis of the acoustic data includes correlating the acoustic data to the specifications of the machine stored in the database, the specifications including acoustic data specifications, and specification for maintenance of the machine;
determine when a first measured parameter for the machine, as measured as part of the analysis of the acoustic data, is outside a first specification of the machine as part of the machine specifications as indicated in the database of specifications for the machine, indicating a first measurement variation from the first specification of the machine, wherein the first measured parameter is based on the acoustic data;
assess when the first measurement variation outside the first specification indicates a problem, the assessing including identifying a part associated with the machine and causally related to the first measurement variation;
assess the first measurement variation to determine a reason for the first measurement variation in relation to the identified part;
identify, as at least part of the reason for the first measurement variation, one or more sources of vibration/wave propagation in one or more machine parts in relation to the machine, based on the first measured parameter for the machine being outside the first specification; and
send an alert to a device with a recommendation or action regarding the identified part, based on the reason for the first measurement variation, and the recommendation or the action being at least in part, a maintenance action for the machine.

16. The system of claim 15, wherein the device is another machine or the device is a first device of a human resource.

17. (canceled)

18. The system of claim 15, wherein the part is a part of the machine, or the part is associated to the machine which includes a machine environment part being operatively communicating with the machine.

19. The system of claim 18, wherein the determining when the first measured specification for the machine being measured as part of the analysis of the acoustic data is a result, at least in part, of a digital twin simulation engine generating a digital twin of the machine.

20. A computer program product for detecting a machine maintenance action at a location using acoustic analysis of the machine to detect a probable maintenance action, the computer program product comprising a computer readable storage medium having program instructions embodied therewith, the program instructions executable by a computer to cause the computer to perform functions, by the computer, comprising the functions to:
receive, at a computer, acoustic data from a plurality of microphones at a location, the microphones receiving sounds from a machine at the location;
analyze the acoustic data with respect to a database of specifications for the machine, the analysis of the acoustic data includes correlating the acoustic data to the specifications of the machine stored in the database, the specifications including acoustic data specifications, and specification for maintenance of the machine;
determine when a first measured parameter for the machine, as measured as part of the analysis of the acoustic data, is outside a first specification of the machine as part of the machine specifications as indicated in the database of specifications for the machine, indicating a first measurement variation from the first specification of the machine, wherein the first measured parameter is based on the acoustic data;
assess when the first measurement variation outside the first specification indicates a problem, the assessing including identifying a part associated with the machine and causally related to the first measurement variation;
assess the first measurement variation to determine a reason for the first measurement variation in relation to the identified part;
identifying, as at least part of the reason for the first measurement variation, one or more sources of vibration/wave propagation in one or more machine parts in relation to the machine, based on the first measured parameter for the machine being outside the first specification; and
send an alert to a device with a recommendation or action regarding the identified part, based on the reason for the first measurement variation, and the recommendation or the action being at least in part, a maintenance action for the machine.

21. The method of claim 1, wherein the reason for the identified part is casually related to the measurement variation and thus the vibration; and the method further comprising;
determining a predicted degree of damages/resonance frequency in the machine; and
prioritizing performing reactive/preventive maintenance on one or more damaged machine parts based on the predicted degree of damages/resonance frequency in the machine.
